(19) United States
(12) Patent Application Publication
(10) Pub. No.: US 2025/0216457 A1
(43) Pub. Date: Jul. 3, 2025

(54) TEST DEVICE PERFORMING TEST OPERATION ON LATCH CIRCUIT, OPERATING METHOD OF TEST DEVICE, AND STORAGE DEVICE

(71) Applicant: SAMSUNG ELECTRONICS CO., LTD., Suwon-si (KR)

(72) Inventor: Sangin PARK, Suwon-si (KR)

(73) Assignee: SAMSUNG ELECTRONICS CO., LTD., Suwon-si (KR)

(21) Appl. No.: 18/977,481

(22) Filed: Dec. 11, 2024

(30) Foreign Application Priority Data
Dec. 27, 2023 (KR) 10-2023-0193183

(51) Int. Cl. G01R 31/3185; G01R 31/317

(52) U.S. Cl. CPC G01R 31/318525; G01R 31/31703; G01R 31/31725

(57) ABSTRACT

Provided is a test device performing a test operation on a latch circuit which includes a plurality of latches. The test device includes a counter configured to output test data to a test target latch, selected from among the plurality of latches, in response to a clock signal and increase a value of the test data in response to the clock signal; a comparison circuit configured to receive, as a first input, the test data outputted from the counter, receive, as a second input, test data outputted from the test target latch, and output a comparison signal by comparing the first input with the second input; and a determination circuit configured to generate a defect determination value indicating whether the latch circuit has a defect, based on the comparison signal.

### CROSS-REFERENCE TO RELATED APPLICATION

This application is based on and claims priority under 35 U.S.C. § 119 to Korean Patent Application No. 10-2023-0193183, filed on Dec. 27, 2023, in the Korean Intellectual Property Office, the disclosure of which is herein incorporated by reference in its entirety.

### BACKGROUND

One or more example embodiments of the disclosure relate to a test device that performs a test operation on a latch circuit.

Memory devices can be classified into volatile memory devices and non-volatile memory devices according to whether the memory devices lose stored data when the power supply is interrupted. The non-volatile memory devices include flash memory devices that are electrically erasable and programmable.

A memory device may input and output data using a plurality of latches. However, if a defect occurs in any one of the plurality of latches included in the memory device, reliability of the memory device may deteriorate. Therefore, there is a need for a method that may accurately determine whether the plurality of latches in the memory device have a defect.

### SUMMARY

One or more example embodiments of the disclosure provide a test device capable of accurately detecting a defect occurring to a plurality of latches.

According to an aspect of an example embodiment of the inventive concept, there is provided a test device performing a test operation on a latch circuit, which includes a plurality of latches, the test device including a counter configured to output test data to a test target latch, selected from among the plurality of latches, in response to a clock signal and increase a value of the test data in response to the clock signal; a comparison circuit configured to receive, as a first input, the test data outputted from the counter, receive, as a second input, test data outputted from the test target latch, and output a comparison signal by comparing the first input with the second input; and a determination circuit configured to generate a defect determination value indicating whether the latch circuit has a defect, based on the comparison signal.

According to an aspect of an example embodiment of the inventive concept, there is provided an operating method of a test device performing a test operation on a latch circuit, which includes a plurality of latches, the operating method including outputting, by a counter of the test device, test data to a test target latch, selected from among the plurality of latches, in response to a clock signal; increasing, by the counter, a value of the test data in response to the clock signal; receiving, as a first input, by a comparison circuit of the test device, the test data outputted from the counter; receiving, as a second input, by the comparison circuit, test data outputted from the test target latch; outputting, by the comparison circuit, a comparison signal by comparing the first input with the second input; and generating, by a determination circuit of the test device, a defect determination value indicating whether the latch circuit has a defect, based on the comparison signal.

According to an aspect of an example embodiment of the inventive concept, there is provided a memory device including a memory cell region including a memory cell array, and a peripheral circuit region connected to the memory cell region. The peripheral circuit region includes a latch circuit including a plurality of latches, and a test device configured to perform a test operation on the latch circuit. The test device includes a counter configured to output test data to a test target latch, selected from among the plurality of latches, in response to a clock signal, and increase a value of the test data in response to the clock signal; a comparison circuit configured to receive, as a first input, the test data outputted from the counter, receive, as a second input, test data outputted from the test target latch, and output a comparison signal by comparing the first input with the second input; and a determination circuit configured to generate a defect determination value indicating whether the latch circuit has a defect, based on the comparison signal.

According to an aspect of an example embodiment of the inventive concept, there is provided a storage device including a non-volatile memory, and a storage controller configured to control an operation of the non-volatile memory. The non-volatile memory includes a latch circuit including a plurality of latches, and a test device configured to perform a test operation on the latch circuit. The test device includes a counter configured to output test data to a test target latch, selected from among the plurality of latches, in response to a clock signal, and configured to increase a value of the test data in response to the clock signal; a comparison circuit configured to receive, as a first input, the test data outputted from the counter, and receive, as a second input, test data outputted from the test target latch and configured to output a comparison signal by comparing the first input with the second input, and a determination circuit configured to generate a defect determination value indicating whether the latch circuit has a defect, based on the comparison signal.

### BRIEF DESCRIPTION OF DRAWINGS

Embodiments will be more clearly understood from the following detailed description taken in conjunction with the accompanying drawings in which:

FIG. 1 is a block diagram illustrating a latch circuit and a test device that determines whether the latch circuit has a defect according to one or more example embodiments;

FIG. 2 is a block diagram illustrating detailed structures of a test device and a latch circuit according to one or more example embodiments;

FIG. 3 is a timing diagram illustrating an example of an operation of a test device according to one or more example embodiments;

FIG. 4 is a timing diagram illustrating another example of an operation of a test device according to one or more example embodiments;

FIG. 5 is a timing diagram illustrating another example of an operation of a test device according to one or more example embodiments;

FIG. 6 is a table illustrating an example of signals and data used for a test device according to one or more example embodiments;

FIG. 7 is a table illustrating another example of signals and data used for a test device according to one or more example embodiments;

FIG. 8 is a flowchart illustrating an operating method of a test device according to one or more example embodiments;

FIG. 9 is a flowchart illustrating a method of outputting a comparison signal in a test device according to one or more example embodiments;

FIG. 10 is a block diagram illustrating a memory device including a test device according to one or more example embodiments;

FIG. 11 is a block diagram illustrating a storage device including a test device according to one or more example embodiments; and

FIG. 12 is a block diagram illustrating an example in which a memory device is applied to a solid state drive (SSD) system, according to one or more example embodiments.

### DETAILED DESCRIPTION

Hereinafter, example embodiments are described in detail with reference to the accompanying drawings.

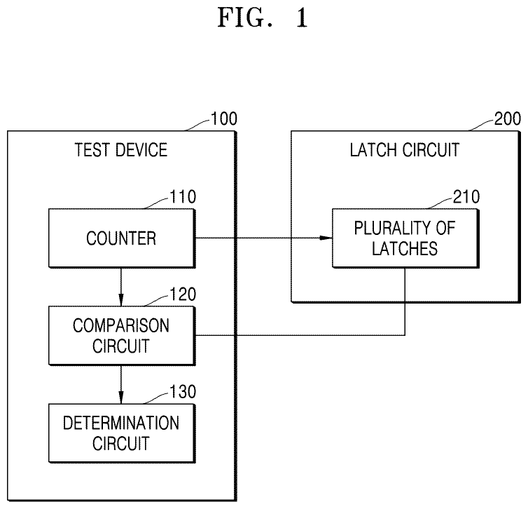

FIG. 1 is a block diagram illustrating a test device and a latch circuit of which the test device determines whether the latch circuit has a defect or not according to one or more example embodiments.

Referring to FIG. 1, a test device 100 according to one or more example embodiments may perform a test operation on a latch circuit 200. The test operation may include an operation for determining whether the latch circuit 200 has a defect or not. The test device 100 may input test data into a plurality of latches 210 included in the latch circuit 200 and may compare test data outputted after passing through the plurality of latches 210 included in the latch circuit 200 with the inputted test data to determine whether the latch circuit 200 has the defect or not.

The latch circuit 200 may include the plurality of latches 210. The test device 100 may determine whether the defect occurs to the plurality of latches 210 in the latch circuit 200.

In an embodiment, the latch circuit 200 may be included in a memory device, but the embodiment is not limited thereto. Unlike as described above, the latch circuit 200 may be included in electronic devices other than the memory device, and the test device 100 may perform the test operation on the latch circuit 200 included in electronic devices other than memory device.

In an embodiment, the latch circuit 200 may be provided on the same chip as the test device 100. For example, the latch circuit 200 may be provided on a memory chip and the test device 100 may be provided on the same memory chip as that on which the latch circuit 200 is provided.

The test device 100 according to one or more example embodiments may include a counter 110, a comparison circuit 120, and a determination circuit 130.

In an embodiment, the counter 110 may output the test data to the latch circuit 200 in response to a clock signal. In addition, the counter 110 may output the test data to the comparison circuit 120 in response to the clock signal.

The test data may include data for determining whether the plurality of latches 210 included in the latch circuit 200 operate normally.

In an embodiment, the counter 110 may increase a value of the test data in response to the clock signal. The test device 100 may output the test data to the latch circuit 200 while increasing the value of the test data through the counter 110, thereby inputting all types of values of the test data that may be inputted into the latch circuit 200.

In an embodiment, the latch circuit 200 may pass the test data through a test target latch selected from among the plurality of latches 210. The test target latch may include a latch on which the test operation is being performed with the test data. The test target latch may receive an input of the test data outputted from the counter 110 and may pass the test data through an internal circuit and output the test data to the comparison circuit 120.

In an embodiment, the comparison circuit 120 may receive, as a first input, the test data outputted from the counter 110. The comparison circuit 120 may receive, as a second input, the test data outputted from the test target latch. The comparison circuit 120 may output a comparison signal by comparing the first input with the second input. The comparison signal may indicate whether the first input is the same as the second input.

In an embodiment, the determination circuit 130 may generate a defect determination value indicating whether the latch circuit 200 has the defect or not, based on the comparison signal.

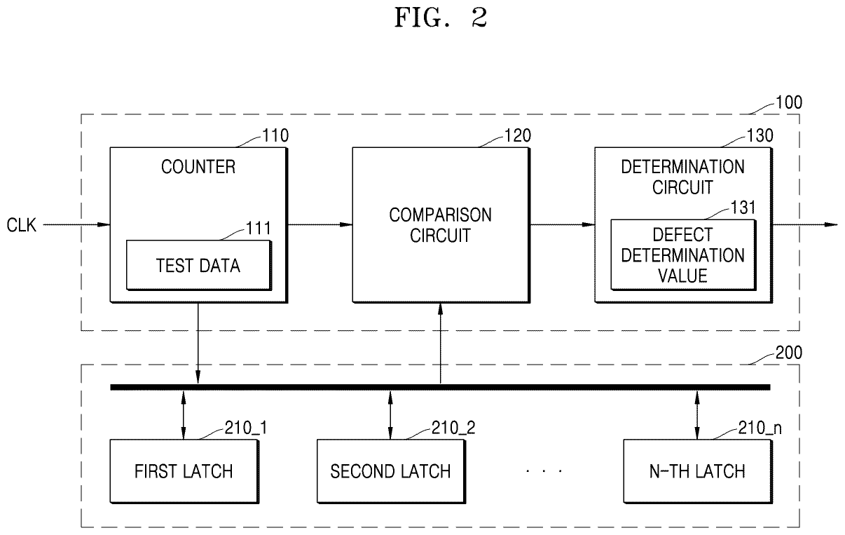

Operations of the test device 100 and the latch circuit 200 described above are described in detail with reference to FIG. 2.

FIG. 2 is a block diagram illustrating detailed structures of a test device and a latch circuit according to one or more example embodiments.

Referring to FIG. 2, a test device 100 according to one or more example embodiments may include a counter 110, a comparison circuit 120, and a determination circuit 130.

The test device 100 may perform a test operation on a latch circuit 200 in response to a test command received from an external device (for example, a defect detection device, a host device, and the like). The test command may include a command to perform the test operation on the latch circuit 200.

The counter 110 may store test data 111. The test data 111 may include data for detecting a defect in any one of a first latch 210_1 to an n-th latch 210_n (n is a natural number of 2 or more) and a value of the test data 111 may be continuously changed by the counter 110.

The counter 110 may receive a clock signal CLK. The counter 110 may receive the clock signal CLK from a clock generator in the test device 100 or a clock generator in a device in which the test device 100 is included.

The counter 110 may output the test data 111 in response to the clock signal CLK.

In an embodiment, the counter 110 may output the test data 111 in response to a first edge of the clock signal CLK. Here, the first edge of the clock signal CLK may be a rising edge, but the embodiment is not limited thereto. The first edge of the clock signal CLK may be a falling edge. In addition, a second edge of the clock signal CLK may be a falling edge, but the embodiment is not limited thereto. The second edge of the clock signal CLK may be a rising edge. The following descriptions are provided with a focus on an embodiment in which the first edge of the clock signal CLK is a rising edge and the second edge of the clock signal CLK is a falling edge.

The counter 110 may output the test data 111 to the latch circuit 200. In addition, the counter 110 may output the test data 111 to the comparison circuit 120.

In addition, the counter 110 may increase a value of the test data 111 in response to the clock signal CLK.

In an embodiment, the counter 110 may increase the value of the test data 111 in response to the first edge of the clock signal CLK. The counter 110 may output the test data 111 to the latch circuit 200 and the comparison circuit 120 in response to the first edge of the clock signal CLK and, at the same time, may increase the value of the test data 111. Here, the counter 110 may output the test data 111 having a value that has not been increased to the latch circuit 200 (that is, having a value before an increase) and the comparison circuit 120 may store therein the test data 111 having a value that has been increased.

In another embodiment, the counter 110 may increase the value of the test data 111 in response to the second edge of the clock signal CLK. That is, the counter 110 may increase the value of the test data 111, after outputting the test data 111 to the latch circuit 200 and the comparison circuit 120, in response to the first edge of the clock signal CLK.

In an embodiment, the counter 110 may increase the value of the test data 111 by 1 in response to the clock signal CLK. For example, if the test data 111 is 8-bit data and the value of the test data 111 stored in the counter 110 is 0 x 00, the counter 110 may increase the value of the test data 111 to 0 x 01 in response to the clock signal CLK. As described above, the counter 110 may increase the value of the test data 111 by 1 in response to the clock signal CLK, thereby outputting the test data 111 having all types of values to the latch circuit 200.

In an embodiment, if the value of the test data 111 is a maximum value, the counter 110 may change the value of the test data 111 to a minimum value in response to the clock signal CLK. For example, if the test data 111 is 8-bit data, the value of the test data 111 may have 0 x FF as the maximum value and 0 x 00 as the minimum value. Here, if the value of the test data 111 is 0 x FF, the value of the test data 111 may be the maximum value. Therefore, the counter 110 may change the value of the test data 111 to 0 x 00 which is the minimum value in response to the clock signal CLK.

The latch circuit 200 according to one or more example embodiments may include a first latch 210_1 to an n-th latch 210_n. In addition, the latch circuit 200 may further include an internal bus.

The latch circuit 200 may receive an input of the test data 111 from the counter 110. Here, the test data 111 may be inputted into the internal bus within the latch circuit 200. The internal bus may transmit the test data 111 to a test target latch selected from among the first latch 210_1 to the n-th latch 210_n.

The test target latch may include a latch on which a test operation is being performed among the first latch 210_1 to the n-th latch 210_n. The latch circuit 200 may select any one latch among the first latch 210_1 to the n-th latch 210_n as the test target latch in response to the test command received from an external device. The test command may include a command to perform the test operation on the latch circuit 200 and may be transmitted to the test device 100 and the latch circuit 200. The internal bus may select the test target latch in response to the test command and may transmit the test data 111 to the selected test target latch.

In an embodiment, if the test operation on the test target latch is completed, the latch circuit 200 may change the test target latch to a latch on which the test operation has not been performed among the first latch 210_1 to the n-th latch 210_n.

If the test data 111 having all types of values is inputted into the test target latch, the latch circuit 200 may determine that the test operation on the test target latch is completed. For example, if the test data 111 is 8-bit data, when the test data 111 having values between 0 x 00 and 0 x FF is all inputted into the test target latch, the latch circuit 200 may determine that the test operation on the test target latch is completed.

If the test operation on the test target latch is completed, the latch circuit 200 may change the test target latch to the latch on which the test operation has not been performed among the first latch 210_1 to the n-th latch 210_n. For example, if the test target latch is a second latch 210_2 and the test operation on the first latch 210_1 is previously completed, once the test operation on the test target latch is completed, the latch circuit 200 may change the test target latch to any one among a third latch 210_3 to the n-th latch 210_n on which the test operation has not been performed.

In an embodiment, the latch circuit 200 may change the test target latch based on indexes of the first latch 210_1 to the n-th latch 210_n. For example, the latch circuit 200 may initially select the first latch 210_1 with an index of 1 as the test target latch and, if the test operation on the test target latch is completed, may change the test target latch while increasing the index of the test target latch by 1.

In another example, the latch circuit 200 may change the test target latch based on addresses of the first latch 210_1 to the n-th latch 210_n. For example, the latch circuit 200 may initially select a latch with an address of 0 x 0000 as the test target latch and, if the test operation on the test target latch is completed, may change the test target latch while increasing the address of the test target latch by 1.

The latch circuit 200 may change the test target latch to a latch on which the test operation has not been performed among the first latch 210_1 to the n-th latch 210_n until the test operation is completed for all the first latch 210_1 to the n-th latch 210_n. Accordingly, the test operation may be performed for all the first latch 210_1 to the n-th latch 210_n included in the latch circuit 200.

In an embodiment, if the value of the test data 111 received from the counter 110 is the maximum value, the latch circuit 200 may change the test target latch after the test data 111 having the maximum value passes through the test target latch. If the value of the test data 111 received from the counter 110 is the maximum value (for example, 0 x FF), the latch circuit 200 may determine that the test data 111 having a value from the minimum value to the maximum value has been all inputted and may thus change the test target latch. Accordingly, the latch circuit 200 may sequentially pass the test data 111 having a value from the minimum value to the maximum value through the changed test target latch.

The comparison circuit 120 may receive a first input and a second input. The first input may include the test data 111 outputted from the counter 110. The second input may include the test data 111 outputted from the test target latch.

The comparison circuit 120 may generate and output a comparison signal based on the first input and the second input. The comparison signal may indicate a result of comparing the first input with the second input.

In an embodiment, if the first input is the same as the second input, the comparison circuit 120 may output the comparison signal having a first value (for example, 0). If the first input is the same as the second input, the test data 111 having passed through the test target latch may be the same as the test data 111 inputted by the counter 110 into the test target latch. That is, if a result of the test data 111 having passed through the test target latch is normal, the comparison circuit 120 may output the comparison signal having the first value.

On the other hand, if the first input is not the same as the second input, the comparison circuit 120 may output the comparison signal having a second value (for example, 1). If the first input is not the same as the second input, the test data 111 having passed through the test target latch may be different from the test data 111 inputted by the counter 110 into the test target latch. That is, if the result of the test data 111 having passed through the test target latch is not normal, the comparison circuit 120 may output the comparison signal having the second value.

In an embodiment, the comparison circuit 120 may include an XOR gate configured to output the comparison signal based on the first input and the second input. The XOR gate may receive the first input and the second input and may output the comparison signal. If the first input is the same as the second input, the XOR gate may output the comparison signal having a value of 0. On the other hand, if the first input is not the same as the second input, the XOR gate may output the comparison signal having a value of 1.

The determination circuit 130 may generate a defect determination value based on the comparison signal. The defect determination value may indicate whether the latch circuit 200 has a defect or not.

In an embodiment, the determination circuit 130 may count a number of times the comparison signal has the second value and may generate the defect determination value. The comparison signal having the second value may indicate that the test data 111 having passed through the test target latch is different from the test data 111 inputted by the counter 110 into the test target latch. That is, the determination circuit 130 may count how many times errors occur to an output of the latch circuit 200 to generate the defect determination value.

Accordingly, the defect determination value of 0 may indicate that the latch circuit 200 has no defect. The defect determination value of more than 0 may indicate that the latch circuit 200 has the defect.

In an embodiment, if the comparison circuit 120 includes the XOR gate, the determination circuit 130 may accumulate values of the comparison signal and may generate the defect determination value based on the accumulated values. In an embodiment, the defect determination value may have a value of the accumulated values.

When the comparison circuit 120 includes the XOR gate, the value of the comparison signal may be 0 if the test data 111 having passed through the test target latch is the same as the test data 111 inputted by the counter 110 into the test target latch. Here, the determination circuit 130 may accumulate the values of the comparison signal and if no error has not occurred to the output of the latch circuit 200, the defect determination value may be 0.

On the other hand, when the comparison circuit 120 includes the XOR gate, the value of the comparison signal may be 1 if the test data 111 having passed through the test target latch is different from the test data 111 inputted by the counter 110 into the test target latch. Here, if the determination circuit 130 accumulates the values of the comparison signal and one or more errors occur to the output of the latch circuit 200, the defect determination value may be 1 or more.

The test device 100 may transmit the defect determination value generated through the determination circuit 130 to the external device. That is, the test device 100 may transmit the defect determination value to the external device in response to the test command received from the external device.

When the test device 100 according to example embodiments described above is used, a test operation may be performed while increasing a value of test data and changing a test target latch to a latch on which a test operation has not been performed among a plurality of latches 210 through a counter 110, and thus whether a latch circuit has a defect or not may be accurately determined.

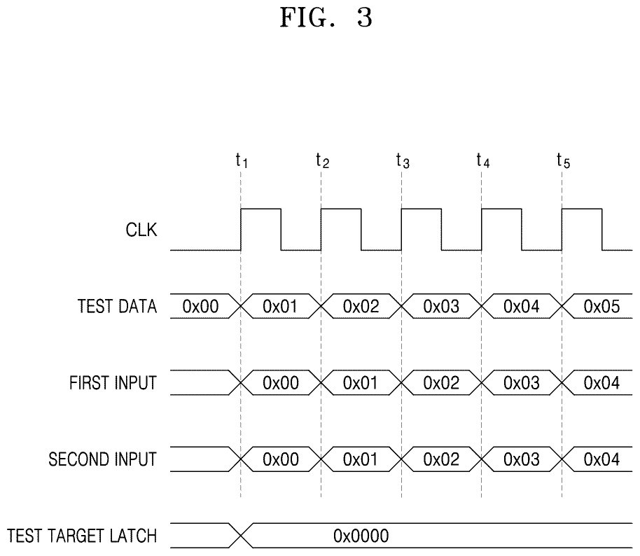

FIG. 3 is a timing diagram illustrating an example of an operation of a test device according to one or more example embodiments.

Referring to FIG. 3, a timing diagram illustrating changes in test data, a first input, a second input, and a test target latch that are based on a clock signal CLK and inputted into a test device 100 according to one or more example embodiments is shown.

In an embodiment described with reference to FIG. 3, a counter 110 of the test device 100 may output the test data in response to a first edge of the clock signal CLK and may increase a value of the test data in response to the first edge of the clock signal CLK.

First, at a first time point t₁ in the timing diagram of FIG. 3, the counter 110 may output the test data having the value of 0 x 00 to a comparison circuit 120 in response to a first edge of the clock signal CLK. Accordingly, a value of the first input that is inputted into the comparison circuit 120 may be 0 x 00.

In addition, at the first time point t₁, the counter 110 may output the test data having the value of 0 x 00 to a latch circuit 200 in response to the first edge of the clock signal CLK. Here, the test data may pass through a latch having an address of 0 x 0000, which is the test target latch, and may be inputted into the comparison circuit 120 as the second input. Here, if the test target latch has no error, a value of the second input that is inputted into the comparison circuit 120 may be 0 x 00.

In addition, at the first time point t₁, the counter 110 may increase the value of the test data from 0 x 00 to 0 x 01 in response to the first edge of the clock signal CLK.

At a second time point t₂, the counter 110 may output the test data having the value of 0 x01 to the comparison circuit 120 and the latch circuit 200 in response to the first edge of the clock signal CLK. Accordingly, the first input having a value of 0 x 01 may be inputted into the comparison circuit 120. In addition, if the test target latch has no error, the second input having a value of 0 x 01 may be inputted into the comparison circuit 120. In addition, at the second time point t₂, the counter 110 may increase the value of the test data from 0 x 01 to 0 x 02 in response to the first edge of the clock signal CLK.

Similarly, at a third time point t₃, a fourth time point t₄, and a fifth time point t₅, the counter 110 may output the test data to the comparison circuit 120 and the latch circuit 200 and may increase the value of the test data in response to the first edge of the clock signal CLK.

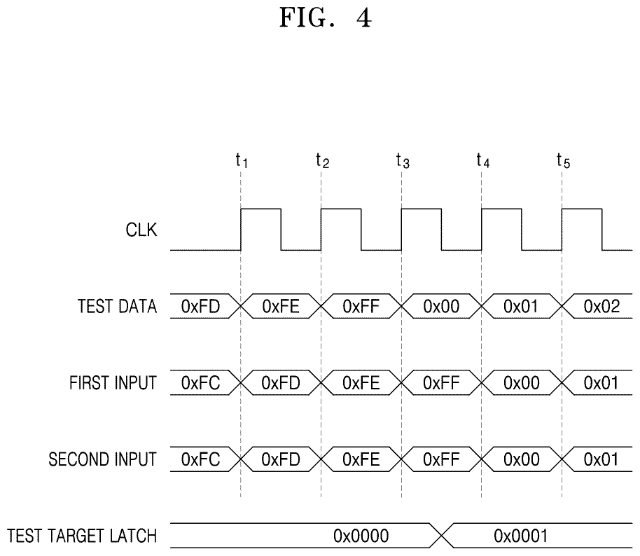

FIG. 4 is a timing diagram illustrating another example of an operation of a test device according to one or more example embodiments.

Referring to FIG. 4, a timing diagram illustrating changes in test data, a first input, a second input, and a test target latch that are based on a clock signal CLK and inputted into a test device 100 according to one or more example embodiments is shown.

In an embodiment described with reference to FIG. 4, as in the embodiment described above with reference to FIG. 3, a counter 110 of the test device 100 may output the test data in response to the first edge of the clock signal CLK and may increase a value of the test data in response to the first edge of the clock signal CLK. Here, the embodiment described with reference to FIG. 4 shows a situation in which the value of the test data is a maximum value so the value of the test data may be changed to a minimum value and the test target latch may be changed.

First, at a first time point t₁ and a second time point t₂ in the timing diagram of FIG. 4, as described above with reference to FIG. 3, the counter 110 may output the test data to a comparison circuit 120 and a latch circuit 200 and may increase the value of the test data in response to the first edge of the clock signal CLK.

At a third time point t₃, the counter 110 may output the test data having the value of 0 x FF to the comparison circuit 120 and the latch circuit 200 in response to the first edge of the clock signal CLK. Accordingly, the first input having a value of 0 x FF may be inputted into the comparison circuit 120. In addition, if the test target latch has no error, the second input having a value of 0 x FF may be inputted into the comparison circuit 120.

In addition, at the third time point t₃, the value of the test data is 0 x FF which is a maximum value, so the counter 110 may not increase the value of the test data. Here, since the value of the test data is 0 x FF which is the maximum value, the counter 110 may change the value of the test data to a minimum value. That is, at the third time point t₃, the counter 110 may change the value of the test data from 0 x FF to 0 x 00 in response to the first edge of the clock signal CLK.

In addition, since the value of the test data received from the counter 110 at the third time point t₃ is 0 x FF which is the maximum value, the latch circuit 200 may change the test target latch after the third time point t₃ that the test data having the maximum value passes through the test target latch. Here, the latch circuit 200 may change the test target latch before a fourth time point t₄ at which the next test data is inputted. In the embodiment described with reference to FIG. 4, the latch circuit 200 may change the test target latch to the latch having an address of 0 x 0001 by increasing the address of the test target latch by 1.

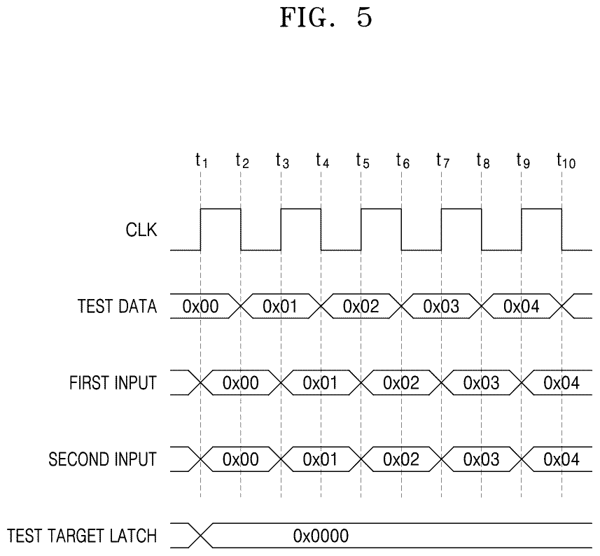

FIG. 5 is a timing diagram illustrating another example of an operation of a test device according to one or more example embodiments.

Referring to FIG. 5, a timing diagram illustrating changes in test data, a first input, a second input, and a test target latch that are based on a clock signal CLK and inputted into a test device 100 according to one or more example embodiments is shown.

In an embodiment described with reference to FIG. 5, a counter 110 of the test device 100 may output the test data in response to a first edge of the clock signal CLK and may increase a value of the test data in response to a second edge of the clock signal CLK.

First, at a first time point t₁ in the timing diagram of FIG. 5, the counter 110 may output the test data having the value of 0 x 00 to a comparison circuit 120 in response to the first edge of the clock signal CLK. Accordingly, a value of the first input that is inputted into the comparison circuit 120 may be 0 x 00.

In addition, at the first time point t₁, the counter 110 may output the test data having the value of 0 x 00 to a latch circuit 200 in response to the first edge of the clock signal CLK. Here, the test data may pass through a latch having an address of 0 x 0000, which is the test target latch, and may be inputted into the comparison circuit 120 as the second input. Here, if the test target latch has no error, a value of the second input that is inputted into the comparison circuit 120 may be 0 x 00.

Next, at a second time point t₂ in the timing diagram of FIG. 5, the counter 110 may increase the value of the test data from 0 x 00 to 0 x 01 in response to the second edge of the clock signal CLK.

At a third time point t₃, the counter 110 may output the test data having the value of 0 x 01 to the comparison circuit 120 and the latch circuit 200 in response to the first edge of the clock signal CLK. Accordingly, the first input having the value of 0 x 01 may be inputted into the comparison circuit 120. In addition, if the test target latch has no error, the second input having the value of 0 x 01 may be inputted into the comparison circuit 120. Next, at a fourth time point t₄, the counter 110 may increase the value of the test data from 0 x 01 to 0 x 02 in response to the second edge of the clock signal CLK.

Similarly, at a fifth time point t₅, a seventh time point t₇, and a ninth time point to, the counter 110 may output the test data to the comparison circuit 120 and the latch circuit 200 in response to the first edge of the clock signal CLK. Next, at a sixth time point t₆, an eighth time point t₈, and a tenth time point t₁₀, the counter 110 may increase the value of the test data in response to the second edge of the clock signal CLK.

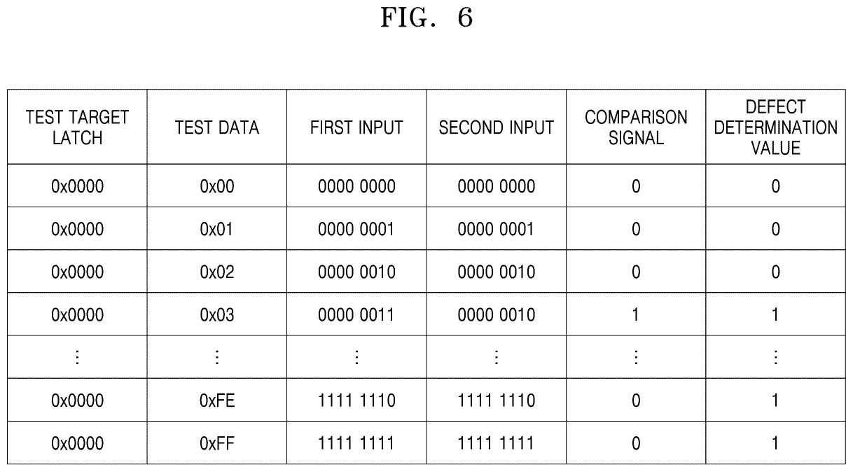

FIG. 6 is a table illustrating an example of signals and data used for a test device according to one or more example embodiments.

Referring to FIG. 6, a table illustrating an example of test data, a first input, a second input, a comparison signal, and a defect determination value according to an operation of a test device 100 according to one or more example embodiments is shown.

In the embodiment described with reference to FIG. 6, a test target latch may include a latch having an address of 0 x 0000 among a plurality of latches 210, and a first value of the comparison signal may be 0 and a second value of the comparison signal may be 1.

First, if the test data is 0 x 00, the first input that is inputted into a comparison circuit 120 may be binary code 0000 0000 which is the same as the test data. Here, the second input that is inputted into the comparison circuit 120 after passing through the test target latch may be the binary code 0000 0000 which is the same as the test data. Since the first input is the same as the second input, the comparison circuit 120 may output a comparison signal having a value of 0 indicating that there is no error with an output of the test target latch. Since the comparison signal has a value of 0, a determination circuit 130 may maintain a defect determination value as _{0.}

Next, if the test data becomes 0 x 01 when the value of the test data is

increased by 1, the second input may be binary code 0000 0001 which is the same as the test data. Accordingly, the comparison signal may become 0 and the defect determination value may maintain 0.

Next, if the test data becomes 0 x 02 when the value of the test data is increased by 1, the second input may be binary code 0000 0010 which is the same as the test data. Accordingly, the comparison signal may become 0 and the defect determination value may maintain 0.

Next, if the test data becomes 0 x 03 when the value of the test data is increased by 1, the first input that is inputted into the comparison circuit 120 may be binary code 0000 0011 which is the same as the test data. Here, the second input that is inputted into the comparison circuit 120 after passing through the test target latch may be the binary code 0000 0010 which is different from the test data. Since the first input is different from the second input, the comparison circuit 120 may output the comparison signal having a value of 1 indicating that there is an error with the output of the test target latch. Since the comparison signal has a value of 1, the determination circuit 130 may increase the defect determination value to 1.

In a similar manner, the test operation may be performed on the test target latch by increasing the value of the test data by 1 until the value of the test data becomes 0 x FF.

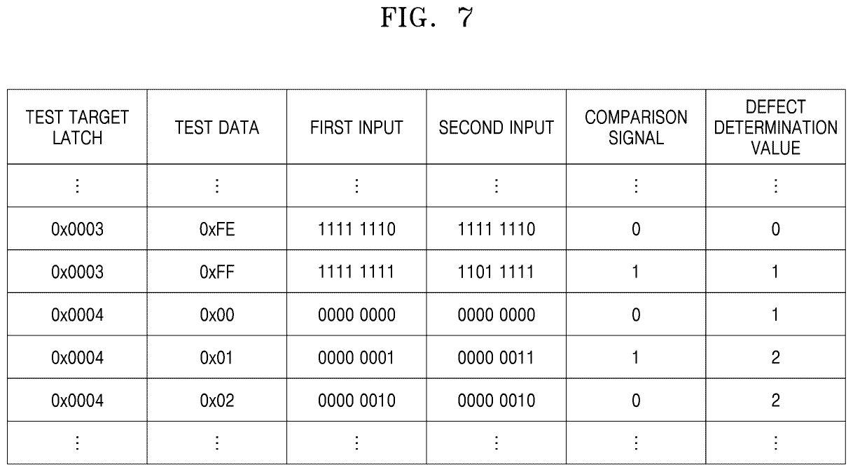

FIG. 7 is a table illustrating another example of signals and data used for a test device according to one or more example embodiments.

Referring to FIG. 7, a table illustrating an example of test data, a first input, a second input, a comparison signal, and a defect determination value according to an operation of a test device 100 according to one or more example embodiments is shown.

The embodiment described with reference to FIG. 7 shows a situation in which a value of the test data is a maximum value and accordingly the value of the test data may be changed to a minimum value and a test target latch may be changed.

In the embodiment described with reference to FIG. 7, the test target latch may include a latch having an address of 0 x 0003 and a latch having an address of 0 x 0004 among a plurality of latches 210, and a first value of the comparison signal may be 0 and a second value of the comparison signal may be 1.

First, if the test data is 0 x FE, the second input may be binary code 1111 1110 which is the same as the test data. Accordingly, the comparison signal may become 0 and the defect determination value may maintain 0.

Next, if the test data becomes 0 x FF by increasing the value of the test data by 1, the first input that is inputted into the comparison circuit 120 may be binary code 1111 1111 which is the same as the test data. Here, the second input that is inputted into the comparison circuit 120 after passing through the test target latch may be binary code 1101 1111 which is different from the test data. Since the first input is different from the second input, the comparison circuit 120 may output the comparison signal having a value of 1 indicating that there is an error with an output of the test target latch. Since the comparison signal has a value of 1, the determination circuit 130 may increase the defect determination value to 1.

Next, since the value of the test data was 0 x FF which is a maximum value, the value of the test data may be changed to 0 x 00 which is a minimum value. In addition, since the test data having 0 x FF which is the maximum value passed through the test target latch, a latch circuit 200 may change the test target latch to a latch having an address of 0 x 0004 by increasing the address of the test target latch by 1.

Next, if the test data is 0 x 00, the second input may be binary code 0000 0000 which is the same as the test data. Accordingly, the comparison signal may become 0 and a defect determination value may maintain 1.

Next, if the test data becomes 0 x 01 by increasing the value of the test data by 1, the first input that is inputted into the comparison circuit 120 may be binary code 0000 0001 which is the same as the test data. Here, the second input that is inputted into the comparison circuit 120 after passing through the test target latch may be binary code 0000 0011 which is different from the test data. Since the first input is different from the second input, the comparison circuit 120 may output the comparison signal having a value of 1 indicating that there is an error with the output of the test target latch. Since the comparison signal has a value of 1, the determination circuit 130 may increase the defect determination value to 2.

Next, if the test data becomes 0 x 02 by increasing the value of the test data by 1, the second input may be binary code 0000 0010 which is the same as the test data. Accordingly, the comparison signal may become 0 and the defect determination value may maintain 2.

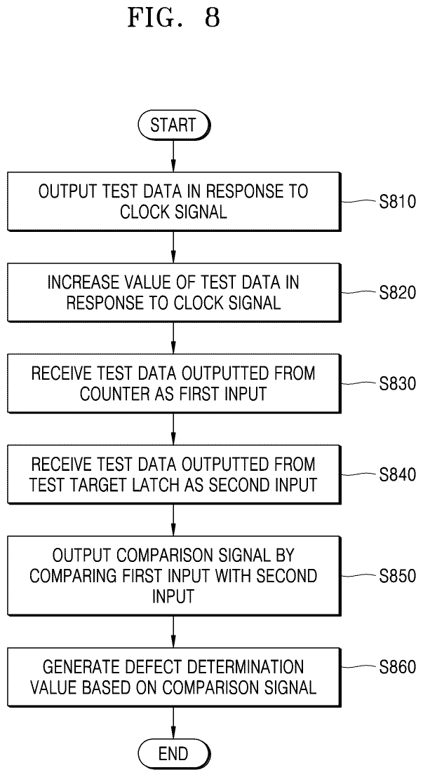

FIG. 8 is a flowchart illustrating an operating method of a test device according to one or more example embodiments.

Referring to FIG. 8, in operation S810, a test device 100 may output test data through a counter 110 in response to a clock signal. The counter 110 may output the test data to a comparison circuit 120 and a latch circuit 200 in response to a first edge of the clock signal.

In operation S820, the test device 100 may increase a value of the test data through the counter 110 in response to the clock signal. The counter 110 may increase the value of the test data in response to the first edge or a second edge of the clock signal. Here, if the counter 110 increases the value of the test data in response to the first edge of the clock signal, the operation S810 and the operation S820 may be performed simultaneously.

In operation S830, the test device 100 may receive, as a first input, the test data outputted from the counter 110 through the comparison circuit 120.

In operation S840, the test device 100 may receive, as a second input, the test data outputted from a test target latch through the comparison circuit 120.

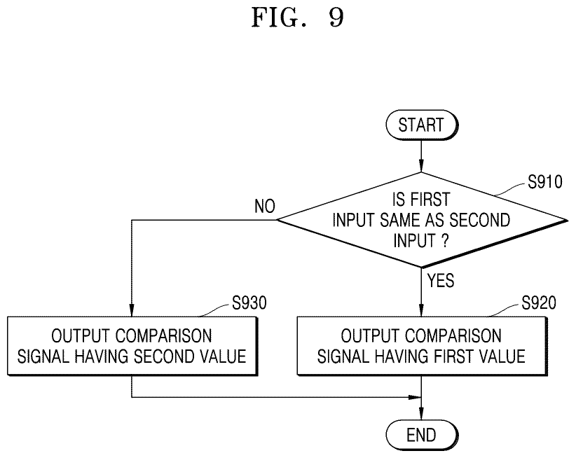

In operation S850, the test device 100 may output a comparison signal by comparing the first input with the second input through the comparison circuit 120. A method of outputting the comparison signal from the comparison circuit 120 is described in detail with reference to FIG. 9.

FIG. 9 is a flowchart illustrating a method of outputting a comparison signal in a test device, according to one or more example embodiments.

Referring to FIG. 9, in operation S910, a test device 100 may determine whether a first input is the same as a second input through a comparison circuit 120. Consequently, the test device 100 may determine if there is an error with an output of a test target latch.

If the first input is determined to be the same as the second input, it indicates that there is no error with the output of the test target latch. Therefore, the process may proceed to operation S920, and the test device 100 may output the comparison signal having a first value through the comparison circuit 120.

If the first input is determined to be different from the second input, it indicates that there is the error with the output of the test target latch. Therefore, the process may proceed to operation S930, and the test device 100 may output the comparison signal having a second value through the comparison circuit 120.

Referring back to FIG. 8, in operation S860, the test device 100 may generate a defect determination value through a determination circuit 130 based on the comparison signal. For example, the determination circuit 130 may count a number of times the comparison signal has the second value and may generate the defect determination value based on the counted number.

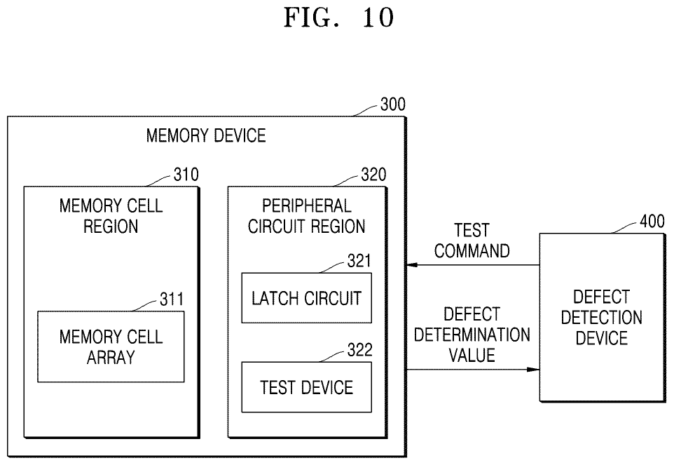

FIG. 10 is a block diagram illustrating a memory device including a test device according to one or more example embodiments.

Referring to FIG. 10, a memory device 300 according to one or more example embodiments may include a memory cell region 310 and a peripheral circuit region 320.

The memory cell region 310 may include a memory cell array 311.

The peripheral circuit region 320 may be connected to the memory cell region 310. The peripheral circuit region 320 may include a row decoder, control logic, page buffer, input/output circuit, voltage generator, and the like.

In an embodiment, the peripheral circuit region 320 may include a latch circuit 321 and a test device 322.

The latch circuit 321 may include a plurality of latches. The latch circuit 321 may be included in general components of the peripheral circuit region 320, such as the page buffer.

The test device 322 may be the same as the test device 100 described above with reference to FIGS. 1 to 9.

The test device 322 may perform a test operation on the latch circuit 321 in response to a test command received from a defect detection device 400 external to the memory device 300. The test device 322 may transmit a defect determination value generated by performing the test operation on the latch circuit 321 to the defect detection device 400.

The defect detection device 400 may include a device for detecting an initial defect occurred to the memory device 300. After being manufactured, the memory device 300 may be examined to detect an initial defect through the defect detection device 400. In an embodiment, the defect detection device 400 may transmit the test command to the memory device 300 and the memory device 300 may perform the test operation on the latch circuit 321 through the internal test device 322 in response to the test command. The memory device 300 may transmit a defect determination value generated by performing the test operation on the latch circuit 321 through the test device 322 to the defect detection device 400. Accordingly, it may be determined whether there is an initial defect in the latch circuit 321 of the memory device 300.

Here, since the memory device 300 performs the test operation on the latch circuit 321 by generating test data using the internal test device 322, the memory device 300 may perform the test operation faster than when the test operation is performed by directly inputting the test data into the latch circuit 321 from the defect detection device 400.

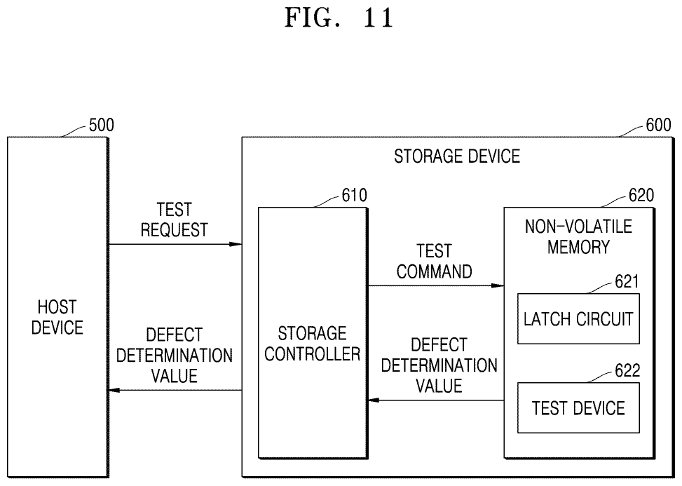

FIG. 11 is a block diagram illustrating a storage device including a test device according to one or more example embodiments.

Referring to FIG. 11, a storage system 50 may include a host device 500 and a storage device 600.

The storage system 50 may be implemented as, for example, a personal computer (PC), a data server, a network-attached storage (NAS), an internet of things (IoT) device, or a portable electronic device. The portable electronic device may include a laptop computer, a mobile phone, a smart phone, a tablet PC, a personal digital assistant (PDA), an enterprise digital assistant (EDA), a digital still camera, a digital video camera, an audio device, a portable multimedia player (PMP), a personal navigation device (PND), an MPEG-1 audio layer 3 (MP3) player, a handheld game console, an e-book, a wearable device, and the like.

The host device 500 may communicate with the storage device 600 through various interfaces and may transmit requests such as a read request, a programming request, and/or an erasing request to the storage device 600. In an embodiment, the host device 500 may be implemented as an application processor (AP) or a system-on-a-chip (SoC).

In an embodiment, the host device 500 may transmit a test request to the storage device 600. The test request may include a request to perform a test operation on a latch circuit 200. In an embodiment, the host device 500 may transmit the test request to the storage device 600 according to a reception of a power off command from a user. In another embodiment, if the storage device 600 is in an idle state, the host device 500 may transmit the test request to the storage device 600.

The storage device 600 may include a storage medium for storing data according to a request from the host device 500. For example, the storage device 600 may include at least one of a solid state drive (SSD), an embedded memory, and a removable external memory. If the storage device 600 is an SSD, the storage device 600 may include a device that compiles with a non-volatile memory express (NVMe) standard.

If the storage device 600 is the embedded memory or external memory, the storage device 600 may include a device that compiles with universal flash storage (UFS) or embedded multi-media card (eMMC) standard. The host device 500 and the storage device 600 may each generate and transmit a packet according to an adopted standard protocol. In an embodiment, the storage device 600 may include an embedded memory built into the storage system 50, such as eMMC or embedded UFS memory devices. In an embodiment, the storage device 600 may include a removable external memory of the storage system 50, such as UFS memory card, a compact flash (CF) memory card, a secure digital (SD) memory card, a micro-SD memory card, a mini-SD memory card, an extreme digital (xD) memory card, or a memory stick.

The storage device 600 according to one or more example embodiments may include a storage controller 610 and a non-volatile memory 620.

The storage controller 610 may control an operation of the non-volatile memory 620 through a channel. The storage controller 610 may control the non-volatile memory 620 to read data stored in the non-volatile memory 620 in response to the read request received from the host device 500. The storage controller 610 may control the non-volatile memory 620 to program data into the non-volatile memory 620 in response to the programming request received from the host device 500. The storage controller 610 may control the non-volatile memory 620 to erase the data stored in the non-volatile memory 620 in response to the erasing request received from the host device 500.

In an embodiment, the non-volatile memory 620 may include a latch circuit 621 and a test device 622.

The latch circuit 621 may include a plurality of latches. The test device 622 may be the same as the test device 100 described above with reference to FIGS. 1 to 9.

In an embodiment, the storage controller 610 may receive the test request from the host device 500. In an embodiment, the test request may be transmitted from the host device 500 to the storage controller 610 according to the reception of the power off command from the user. In another embodiment, if the storage device 600 is in the idle state, the test request may be transmitted from the host device 500 to the storage controller 610.

The storage controller 610 may transmit a test command to the test device 622 of the non-volatile memory 620 in response to the test request received from the host device 500.

The test device 622 may perform the test operation on the latch circuit 621 in response to the test command received from the storage controller 610. The test device 622 may transmit a defect determination value generated by performing the test operation on the latch circuit 621 to the storage controller 610.

The storage controller 610 may transmit the defect determination value received from the test device 622 to the host device 500.

As described above, the storage device 600 according to the inventive concept may periodically determine whether a defect occurs to the latch circuit 621 by performing the test operation on the latch circuit 621, for example, when the storage device 600 receives the power off command from a user or is in the idle state.

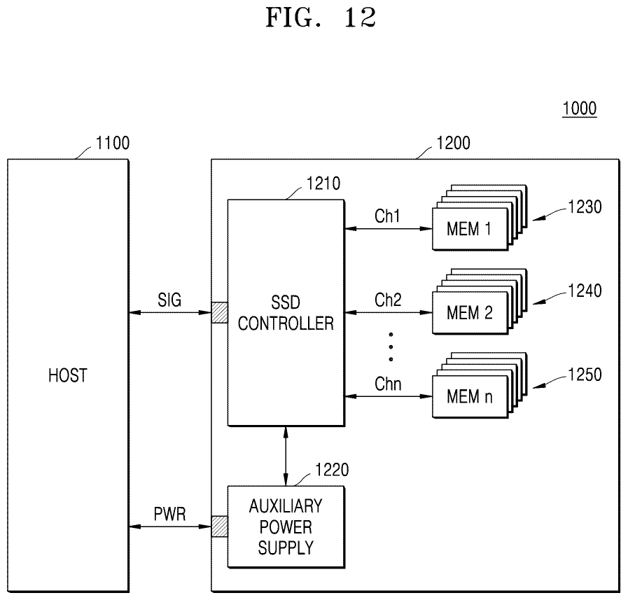

FIG. 12 is a block diagram illustrating an example in which a memory device is applied to an SSD system, according to one or more example embodiments.

Referring to FIG. 12, an SSD system 1000 may include a host 1100 and an SSD 1200. The SSD 1200 may exchange signals SIG with the host 1100 via a signal connector and may receive power PWR via a power connector. The SSD 1200 may include an SSD controller 1210, an auxiliary power supply 1220, and memory devices 1230, 1240, and 1250. The memory devices 1230, 1240, and 1250 may include vertically stacked Not AND (NAND) flash memory devices. Here, the memory devices 1230, 1240, and 1250 included in the SSD 1200 may be implemented with the embodiment described above with reference to FIG. 10 and may include the test device 100 described above with reference to FIGS. 1 to 9.

While the inventive concept has been particularly shown and described with reference to example embodiments thereof, it will be understood that various changes in form and details may be made therein without departing from the spirit and scope of the following claims and their equivalents.

1. A test device performing a test operation on a latch circuit, which includes a plurality of latches, the test device comprising:
a counter configured to output test data to a test target latch, selected from among the plurality of latches, in response to a clock signal and increase a value of the test data in response to the clock signal;
a comparison circuit configured to receive, as a first input, the test data outputted from the counter, receive, as a second input, test data outputted from the test target latch, and output a comparison signal by comparing the first input with the second input; and
a determination circuit configured to generate a defect determination value indicating whether the latch circuit has a defect, based on the comparison signal.

2. The test device of claim 1, wherein the counter is configured to:
output the test data in response to a first edge of the clock signal; and
increase the value of the test data in response to the first edge of the clock signal.

3. The test device of claim 1, wherein the counter is configured to:
output the test data in response to a first edge of the clock signal; and
increase the value of the test data in response to a second edge of the clock signal.

4. The test device of claim 1, wherein the counter is configured to increase the value of the test data by 1 in response to the clock signal.

5. The test device of claim 1, wherein, based on the value of the test data being a maximum value, the counter is configured to change the value of the test data to a minimum value in response to the clock signal.

6. The test device of claim 1, wherein, based on the test operation on the test target latch being completed, the test target latch is changed to a latch, on which the test operation has not been performed, among the plurality of latches.

7. The test device of claim 1, wherein the comparison circuit is configured to:
output the comparison signal having a first value based on the first input being the same as the second input; and
output the comparison signal having a second value based on the first input being not the same as the second input.

8. The test device of claim 7, wherein the determination circuit is configured to count a number of times the comparison signal has the second value and generate the defect determination value based on the counted number.

9. The test device of claim 1, wherein the comparison circuit includes an XOR gate configured to output the comparison signal based on the first input and the second input.

10. The test device of claim 9, wherein the determination circuit is configured to accumulate values of the comparison signal and generate the defect determination value based on the accumulated values.

11. The test device of claim 1, wherein the test device is configured to:
perform the test operation on the latch circuit in response to a test command received from an external device; and
transmit the defect determination value to the external device.

12-19. (canceled)

20. A memory device comprising:
a memory cell region including a memory cell array; and
a peripheral circuit region connected to the memory cell region,
wherein the peripheral circuit region includes:
a latch circuit including a plurality of latches; and
a test device configured to perform a test operation on the latch circuit, and
wherein the test device includes:
a counter configured to output test data to a test target latch, selected from among the plurality of latches, in response to a clock signal and increase a value of the test data in response to the clock signal;
a comparison circuit configured to receive, as a first input, the test data outputted from the counter, receive, as a second input, test data outputted from the test target latch, and output a comparison signal by comparing the first input with the second input; and
a determination circuit configured to generate a defect determination value indicating whether the latch circuit has a defect, based on the comparison signal.

21. The memory device of claim 20, wherein the test device is configured to:
perform the test operation on the latch circuit in response to a test command received from an external defect detection device; and
transmit the defect determination value to the external defect detection device.

22. The memory device of claim 21, wherein the latch circuit is configured to select any one of the plurality of latches as the test target latch in response to the test command.

23. The memory device of claim 22, wherein, based on the test operation on the test target latch being completed, the latch circuit is configured to change the test target latch to a latch on which the test operation has not been performed among the plurality of latches.

24. The memory device of claim 23, wherein, based on the value of the test data received from the counter being a maximum value, the latch circuit is configured to change the test target latch after the test data having the maximum value passes through and output from the test target latch.

25. A storage device comprising:
a non-volatile memory; and
a storage controller configured to control an operation of the non-volatile memory,
wherein the non-volatile memory includes:
a latch circuit including a plurality of latches; and
a test device configured to perform a test operation on the latch circuit, and
wherein the test device includes:
a counter configured to output test data to a test target latch, selected from among the plurality of latches, in response to a clock signal and increase a value of the test data in response to the clock signal;
a comparison circuit configured to receive, as a first input, the test data outputted from the counter, receive, as a second input, test data outputted from the test target latch, and output a comparison signal by comparing the first input with the second input; and
a determination circuit configured to generate a defect determination value indicating whether the latch circuit has a defect, based on the comparison signal.

26. The storage device of claim 25, wherein the storage controller is configured to transmit a test command to the test device in response to a test request received from an external host device,
wherein the test device is configured to perform the test operation on the latch circuit in response to the test command, and transmit the defect determination value to the storage controller, and
wherein the storage controller is configured to transmit the defect determination value to the external host device.

27. The storage device of claim 26, wherein the test request is transmitted to the storage controller from the external host device according to a reception of a power off command.

28. The storage device of claim 26, wherein, based on the storage device being in an idle state, the test request is transmitted to the storage controller from the external host device.
